(19) United States
(12) Patent Application Publication
(10) Pub. No.: US 2012/0146343 A1
(43) Pub. Date: Jun. 14, 2012

(54) BUTTON POSITION RECTIFYING MECHANISM

(75) Inventors: TING-TING ZHAO, Shenzhen City (CN); XIAO-HUI ZHOU, Shenzhen City (CN); MIN-LI LI, Shenzhen City (CN); HONG LI, Shenzhen City (CN)

(73) Assignees: HON HAI PRECISION INDUSTRY CO., LTD., Taipei Hsien (TW); HONG FU JIN PRECISION INDUSTRY (ShenZhen) CO., LTD., Shenzhen City (CN)

(21) Appl. No.: 12/981,567

(22) Filed: Dec. 30, 2010

(30) Foreign Application Priority Data
Dec. 13, 2010 (CN) 201010584914.9

(51) Int. Cl. H05K 5/02

(52) U.S. Cl. 292/145

(57) ABSTRACT

An exemplary button position rectifying structure includes a cover, a button, and a slide bar located at an inner side of the cover. The button includes a body, an engaging portion and a pair of guiding posts extending from the body. The cover defines a through hole therein. The button is received in the through hole of the cover. The cover defines two guiding holes in the inner side thereof. The guiding posts of the button are received in the guiding holes of the cover, respectively. The slide bar engages with the engaging portion of the button to push the button to move along an axis of the through hole of the cover. Each guiding post of the button abuts one side of the guiding hole of the cover, so that the body of the button is located at a center of the through hole of the cover.

### BACKGROUND

1. Technical Field

The disclosure relates to electronic devices, and particularly to a button position rectifying mechanism of an electronic device.

2. Description of Related Art

An electronic device, such as a DVD (Digital Video Disc) player, generally includes a casing, a button embedded in the casing, and a slide element located in the casing and engaging with the button. The casing defines a through hole therein. The button is received in the through hole of the casing. For a user to be able to press the button in the through hole more smoothly, a size of the through hole is a little larger than that of the button. However, under a pushing force of the slide element, a center of the button may be offset from a center of the through hole, and the button may abut an inner wall of the casing around the through hole. This results in friction being generated between the button and the inner wall of the casing.

What is needed, therefore, is a means in an electronic device which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a button position rectifying mechanism in accordance with one embodiment of the disclosure.

FIG. 2 is an isometric view of the button position rectifying mechanism of FIG. 1, but showing the button position rectifying mechanism inverted.

FIG. 3 is an isometric, exploded view of the button position rectifying mechanism of FIG. 1.

FIG. 4 is similar to FIG. 3, but showing all the parts of the button position rectifying mechanism inverted.

FIG. 5 is an enlarged top plan view of part of the button position rectifying mechanism of FIG. 2.

### DETAILED DESCRIPTION

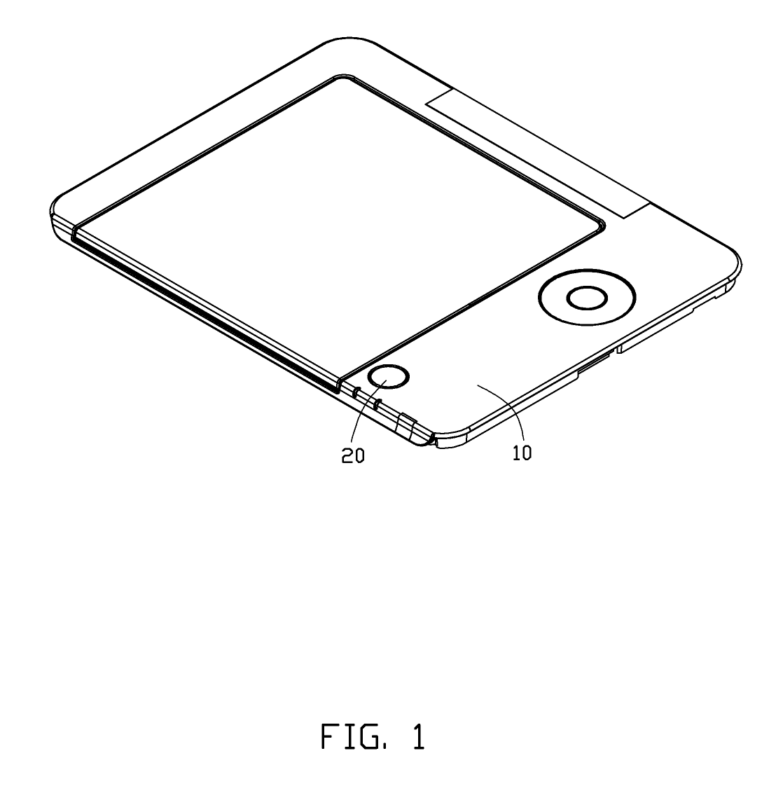

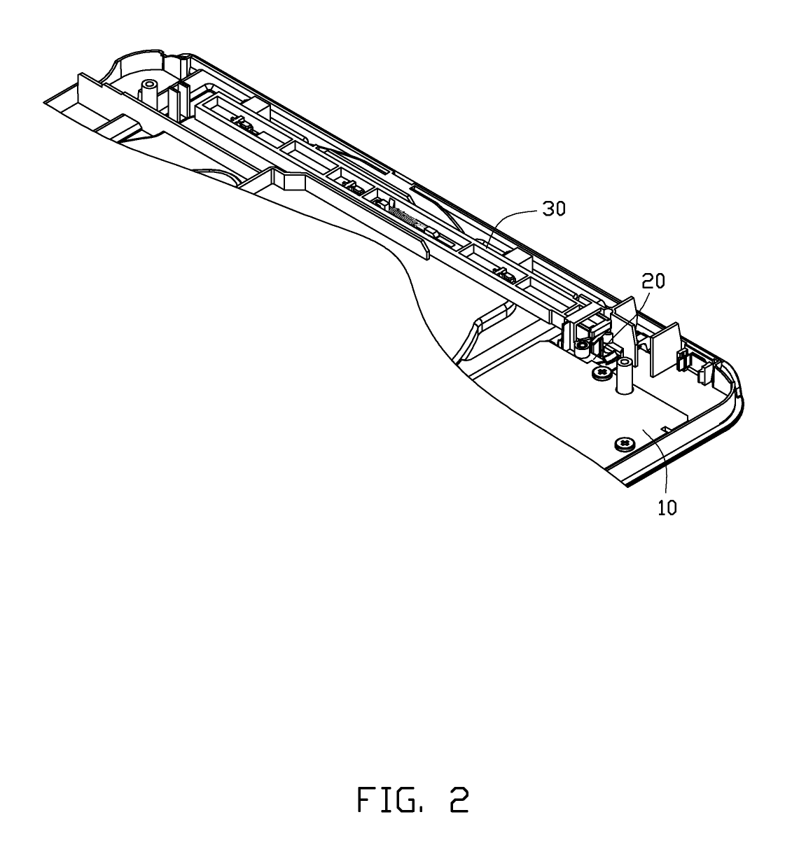

Referring to FIGS. 1-2, a button position rectifying mechanism in accordance with an embodiment of the disclosure is shown. The button position rectifying mechanism can be used in an electronic device such as a DVD player to open or close the electronic device. The button position rectifying mechanism includes a cover 10, a button 20 received in the cover 10, and an elongated slide bar 30 located at an inner side of the cover 10 and engaging with the button 20.

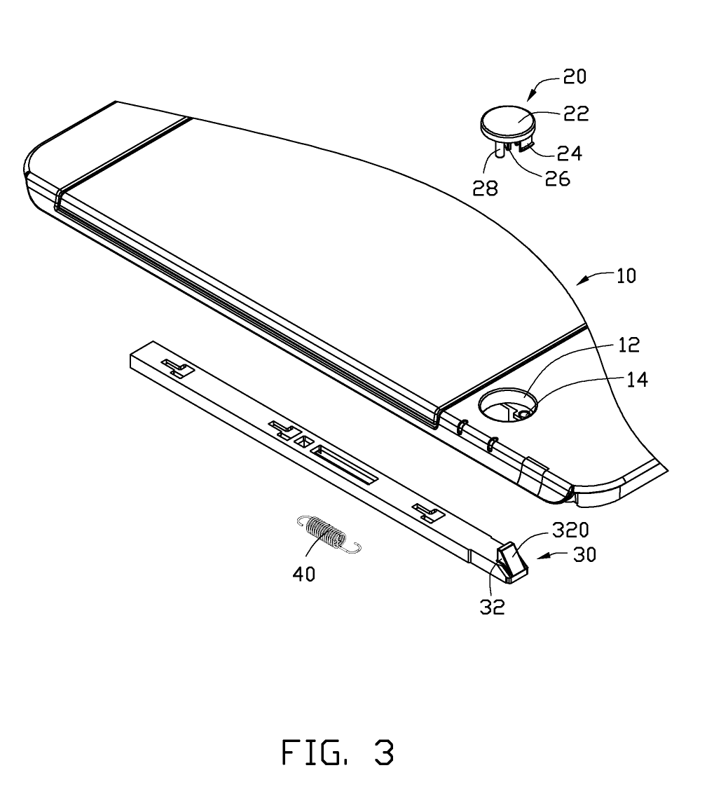

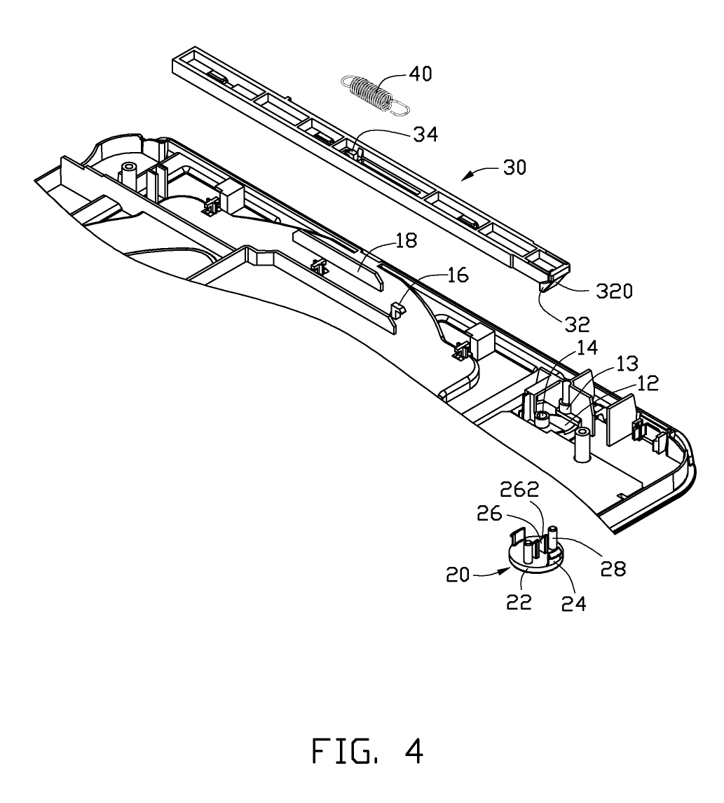

Also referring to FIGS. 3-4, the button 20 is integrally formed as one monolithic piece, and includes a disk-shaped body 22, a pair of opposing buckles 24 extending downwardly from an edge of a bottom face of the body 22, two parallel engaging portions 26 extending downwardly from a center of the bottom face of the body 22, and a pair of guiding posts 28 located at two lateral sides of the engaging portions 26. A top face of the body 22 of the button 20 is a flat face. The buckles 24 buckle the button 20 in the cover 10. Each engaging portion 26 is substantially right triangle-shaped, and has an inclined face 262 facing and engaging with the slide bar 30. Each guiding post 28 is cylindrical, and the two guiding posts 28 have a same diameter.

The slide bar 30 is substantially rectangular, and includes a wedge-shaped engaging block 32 protruding upwardly from a distal end of the slide bar 30, and a first hook 34 formed at a middle of the slide bar 30. The engaging block 32 has an inclined engaging face 320. The engaging face 320 contacts the inclined faces 262 of the engaging portions 26 of the button 20.

The cover 10 defines a circular through hole 12 in an outer face thereof. The through hole 12 has a diameter larger than that of the body 22 of the button 20. The button 20 is received in the through hole 12 of the cover 10. Two protrusions 13 protrude downwardly from an inner face of the cover 10, corresponding to the button 20. Each protrusion 13 defines a circular guiding hole 14 corresponding to a respective guiding post 28 of the button 20. Each guiding hole 14 has a diameter a little larger than that of the guiding post 28. The guiding posts 28 of the button 20 are received in the guiding holes 14 of the cover 10, respectively. Two parallel protruding walls 18 protrude perpendicularly downwardly from the inner face of the cover 10, corresponding to the slide bar 30. The slide bar 30 is located between the two protruding walls 18. A second hook 16 protrudes from the inner face of the cover 10.

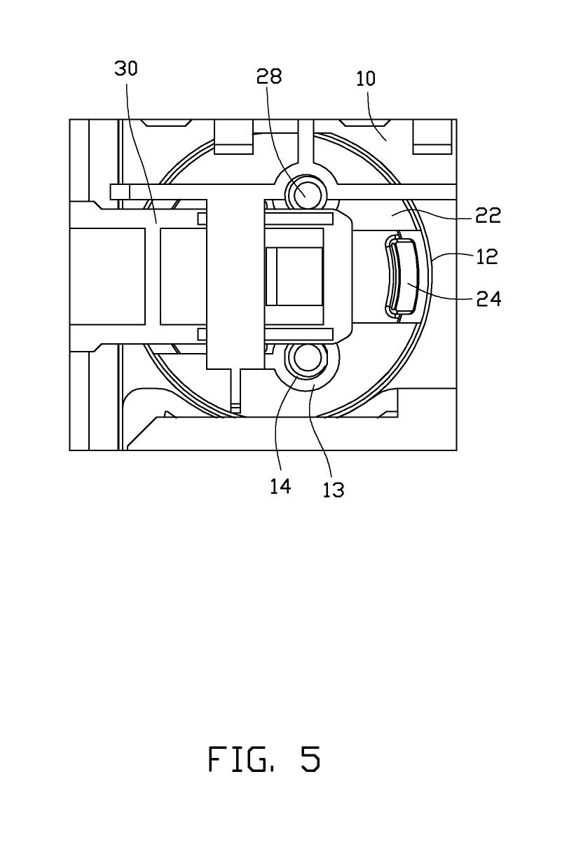

Also referring to FIG. 5, the slide bar 30 is disposed at one side of the button 20. Two ends of a spring 40 are respectively clamped at the first hook 34 of the slide bar 30 and the second hook 16 of the cover 10. The spring 40 deforms resiliently and exerts a resilient force on the slide bar 30. The slide bar 30 abuts the engaging portions 26 of the button 20 rightward to push the button 20 to move along an axis of the through hole 12 of the cover 10. Under a pushing force of the slide bar 30, each guiding post 28 of the button 20 is offset from a center of the corresponding guiding hole 14 of the cover 10 and abuts a right side of the corresponding guiding hole 14 of the cover 10, so that the body 22 of the button 20 is located at a center of the through hole 12 of the cover 10.

When the button 20 in the through hole 12 of the cover 10 is pressed downwardly, each guiding post 28 of the button 20 moves downwardly along the corresponding guiding hole 14 of the cover 10, the engaging portions 26 of the button 20 abut the engaging block 32 of the slide bar 30 to make the slide bar 30 move leftward away from the button 20, and the spring 40 between the slide bar 30 and the cover 10 further deforms resiliently. The spring 40 deforms resiliently at all times to make the slide bar 30 always abut the button 20 whether the button 20 is pressed or not. Thereby, the center of each guiding post 28 of the button 20 is offset from the center of the corresponding guiding hole 14 of the cover 10 and abuts the right side of the corresponding guiding hole 14 of the cover 10, and the body 22 of the button 20 is always located at the center of the through hole 12 of the cover 10. Thus the button 20 is prevented from being offset from the center of the through hole 12 of the cover 10 and abutting an inner wall of the through hole 12 of the cover 10. A gap between the button 20 and the through hole 12 of the cover 10 is more homogeneously maintained. When the button 20 is pressed down in the through hole 12 of the cover 10, friction between the button 20 and the inner wall of the through hole 12 of the cover 10 is avoided.

It is believed that the embodiment(s) and its advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A button position rectifying mechanism for an electronic device, the button position rectifying mechanism comprising:
a cover defining a through hole therein, two guiding holes being defined in an inner side of the cover;
a button comprising:
a body having a diameter smaller than a diameter of the through hole of the cover, the body being received in the through hole of the cover and located at a center of the through hole of the cover;
an engaging portion extending from a center of the body; and
a pair of guiding posts located at two lateral sides of the engaging portion, each guiding hole of the cover having a diameter larger than a diameter of a corresponding one of the guiding posts, the guiding posts being received in the guiding holes of the cover respectively, each of the guiding posts being offset from a center of a corresponding guiding hole of the cover and abutting one side of a sidewall of the corresponding guiding hole of the cover; and
a slide bar located at the inner side of the cover, the slide bar engaging with the engaging portion of the button to push the button to move along an axis of the through hole of the cover.

2. The button position rectifying mechanism of claim 1, wherein the button further comprises a pair of buckles extending from an edge of the body, the buckles buckling the button in the through hole of the cover.

3. The button position rectifying mechanism of claim 2, further comprising a spring, the slide bar further comprising a first hook formed at the slide bar, a second hook protruding from the inner side of the cover, two ends of the spring being respectively clamped at the first hook of the slide bar and the second hook of the cover, the spring deforming resiliently and exerting a resilient force on the slide bar to make the slide bar abut the button.

4. The button position rectifying mechanism of claim 3, wherein two parallel protruding walls protrude from the inner side of the cover, the slide bar being located between the two protruding walls.

5. The button position rectifying mechanism of claim 2, wherein the buckles are opposite to each other.

6. The button position rectifying mechanism of claim 1, wherein the engaging portion has an inclined face, the slide bar comprising a wedge-shaped engaging block protruding from a distal end of the slide bar, the engaging block having an inclined engaging face, the engaging face contacting the inclined face of the engaging portion of the button.

7. The button position rectifying mechanism of claim 6, further comprising a spring, the slide bar further comprising a first hook formed at the slide bar, a second hook protruding from the inner side of the cover, two ends of the spring being respectively clamped at the first hook of the slide bar and the second hook of the cover, the spring deforming resiliently and exerting a resilient force on the slide bar to make the slide bar abut the button.

8. The button position rectifying mechanism of claim 7, wherein two parallel protruding walls protrude from the inner side of the cover, the slide bar being located between the two protruding walls.

9. The button position rectifying mechanism of claim 1, wherein the engaging portion is substantially right triangle-shaped, the slide bar comprising a wedge-shaped engaging block protruding from a distal end of the slide bar, the engaging face of the slide bar engaging with the engaging portion of the button.

10. The button position rectifying mechanism of claim 1, wherein each of the guiding post of the button is cylindrical, the guiding posts having a same diameter.

11. The button position rectifying mechanism of claim 1, further comprising a spring, the slide bar further comprising a first hook formed at the slide bar, a second hook protruding from the inner side of the cover, two ends of the spring being respectively clamped at the first hook of the slide bar and the second hook of the cover, the spring deforming resiliently and exerting a resilient force on the slide bar to make the slide bar abut the button.

12. The button position rectifying mechanism of claim 11, wherein two parallel protruding walls protrude from the inner side of the cover, the slide bar being located between the two protruding walls.

13. The button position rectifying mechanism of claim 1, wherein two parallel protruding walls protrude from the inner side of the cover, the slide bar being located between the two protruding walls.

14. The button position rectifying mechanism of claim 1, wherein the through hole of the cover is circular, and the body of the button is disk-shaped.

15. The button position rectifying mechanism of claim 1, wherein each of the guiding holes of the cover is circular, and each of the guiding posts of the button is cylindrical.

16. The button position rectifying mechanism of claim 1, wherein two protrusions protrude from the inner side of the cover, each of the guiding holes is defined in a corresponding protrusion.

17. A button position setting mechanism for an electronic device, the button position setting mechanism comprising:
a cover defining a through hole therein, two guiding holes being defined in an inner side of the cover, two parallel protruding walls protruding from the inner side of the cover;
a button comprising:
a body having a diameter smaller than a diameter of the through hole of the cover, the body being received in the through hole of the cover and located at a center of the through hole of the cover;
an engaging portion extending from the body; and
a pair of guiding posts extending from the body, each guiding hole of the cover having a diameter larger than a diameter of a corresponding one of the guiding posts, the guiding posts being received in the guiding holes of the cover, respectively, each of the guiding posts being offset from a center of the corresponding guiding hole of the cover and abutting one side of a sidewall of the corresponding guiding hole of the cover; and
a slide bar slidably located between the two protruding walls of the cover, the slide bar engaging with the engaging portion of the button to push the button to move along an axis of the through hole of the cover.

18. The button position setting mechanism of claim 17, wherein the engaging portion extends from a center of the body, and the guiding posts are located at two lateral sides of the engaging portion.

19. The button position setting mechanism of claim 17, further comprising a spring, the slide bar further comprising a first hook formed at the slide bar, a second hook protruding from the inner side of the cover, two ends of the spring being respectively clamped at the first hook of the slide bar and the second hook of the cover, the spring deforming resiliently and exerting a resilient force on the slide bar to make the slide bar abut the button.

20. The button position setting mechanism of claim 17, wherein the button further comprises a pair of buckles extending from an edge of the body, the buckles buckling the button in the through hole of the cover.
